(19) United States
(12) Patent Application Publication
(10) Pub. No.: US 2010/0163943 A1
(43) Pub. Date: Jul. 1, 2010

(54) SEMICONDUCTOR MEMORY DEVICE

(75) Inventor: Tohru Ozaki, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/559,358

(22) Filed: Sep. 14, 2009

(30) Foreign Application Priority Data
Sep. 24, 2008 (JP) 2008-244358

(51) Int. Cl. H01L 27/115; H01L 21/8246

(52) U.S. Cl. 257/295; 438/3; 257/379; 257/E21.664; 257/E27.104

(57) ABSTRACT

A memory includes a first interlayer on transistors; a first and second plugs connected to the transistor; ferroelectric capacitors; a second interlayer covering a side surface of the capacitor; a local interconnection connecting the second plug to the upper electrode, wherein two upper electrodes adjacent to each other on the second plug are connected to the second plug, the lower electrodes adjacent to each other on the first plug are connected to the first plug, cell blocks comprising the connected capacitors are arranged, cell blocks adjacent to each other are arranged to be shifted by a half pitch of the local interconnection, a first gap between two capacitors adjacent to each other on the second plug is larger than twice a thickness of the second interlayer, and a second gap between the cell blocks adjacent to each other is smaller than twice the thickness of the second interlayer.

### CROSS-REFERENCE TO RELATED APPLICATION

This application is based upon and claims the benefit of priority from the prior Japanese Patent Applications No. 2008-244358, filed on Sep. 24, 2008, the entire contents of which are incorporated herein by reference.

### BACKGROUND OF THE INVENTION

1. Field of the Invention

The present invention relates to a semiconductor memory device.

2. Related Art

Ferroelectric memories have attracted attention as one of non volatile semiconductor memories. “Series connected TC unit type ferroelectric RAM” (hereinafter, also “ferroelectric memory” simply) have been developed recently (Patent Documents 1 and 2).

A lower electrode for a ferroelectric capacitor is connected to a cell transistor by a conductive contact plug under the ferroelectric capacitor. This is called a COP (Capacitor On Plug) structure. Because polarization characteristics of the ferroelectric capacitor are degraded by a reducing process of hydrogen, a hydrogen barrier film is used frequently to protect the ferroelectric capacitor from hydrogen.

A via hole reaching a source or a drain of the cell transistor is formed between two adjacent ferroelectric capacitors in the ferroelectric memories. An upper electrode of the ferroelectric capacitor is connected via the via hole to the source or the drain of the cell transistor.

A tungsten plug is usually buried in the via hole. To bury the tungsten plug in the via hole, MO-CVD (Metalorganic-Chemical Vapor Deposition) generating a large amount of hydrogen must be used. The ferroelectric capacitor may be degraded by a large amount of hydrogen introduced in the via hole even if it is protected by the hydrogen barrier film, due to oxygen vacancy generation in the ferroelectric capacitors.

### SUMMARY OF THE INVENTION

A semiconductor memory device according to an embodiment of the present invention comprises: a semiconductor substrate; a plurality of transistors on the semiconductor substrate; a word line connected to a gate of the transistor or serving as the gate; a first interlayer film on a source and a drain of the transistor; a first plug passing thorough the first interlayer film to be connected to one of the source or the drain of the transistor; a second plug passing through the first interlayer film to be connected to the other the source or the drain of the transistor; a ferroelectric capacitor comprising a lower electrode above the first plug electrically connected to the first plug, a ferroelectric film on the lower electrode, and an upper electrode on the ferroelectric film; a second interlayer film covering a side surface of the ferroelectric capacitor; a local interconnection on the second interlayer film connecting the second plug to the upper electrode; and a bit line connected to the local interconnection, wherein
the upper electrodes of two ferroelectric capacitors adjacent to each other on the second plug in a direction the bit line extends are connected to the second plug by the local interconnection,
the lower electrodes of two ferroelectric capacitors adjacent to each other on the first plug in the direction the bit line extends are connected to the first plug,
a plurality of cell blocks each of which comprises the ferroelectric capacitors connected to each other by the first and the second plugs are arranged,

two cell blocks adjacent to each other in a direction the word line extends are arranged to be shifted from each other by a half pitch of the local interconnection,
a first gap between two ferroelectric capacitors adjacent to each other on sides of the second plug in the direction the bit line extends is larger than twice a deposited thickness of the second interlayer film, and

a second gap between the two cell blocks adjacent to each other in the direction the word line extends is smaller than twice the deposited thickness of the second interlayer film.

A manufacturing method of a semiconductor memory device according to an embodiment of the present invention comprises: forming a plurality of transistors on a semiconductor substrate; forming a first plug connected to one of a source or a drain of the transistor and a second plug connected to the other of the source or the drain of the transistor; forming a ferroelectric capacitor above the first plug; forming a second interlayer film on a side surface of the ferroelectric capacitor; and forming a local interconnection on the second interlayer film, wherein

the local interconnection connects upper electrodes of two ferroelectric capacitors adjacent to each other on the second plug to the second plug,

the first plug is connected to lower electrodes of two ferroelectric capacitors adjacent to each other on the first plug;

a plurality of cell blocks each of which comprises the ferroelectric capacitors connected by the first and the second plugs are arranged,

two adjacent cell blocks are arranged to be shifted by a half pitch of the local interconnection,

a first gap between two ferroelectric capacitors adjacent to each other on sides of the second plug is larger than twice a deposited thickness of the second interlayer film, and

a second gap between adjacent two cell blocks is smaller than twice the deposited thickness of the second interlayer film.

### BRIEF DESCRIPTION OF THE DRAWINGS

FIG. 1 is a circuit diagram showing a configuration of a ferroelectric memory according a first embodiment of the present invention;

FIG. 2 is a layout diagram showing a planar configuration of part of the ferroelectric memory;

FIG. 3 is a cross-sectional view along a line 3-3 shown in FIG. 2;

FIG. 4 is a cross-sectional view along a line 4-4 shown in FIG. 2;

FIGS. 5A to 8B show a manufacturing method of the ferroelectric memory according to the first embodiment;

FIGS. 9 and 10 are cross-sectional views showing a configuration of a ferroelectric memory according to a second embodiment of the present invention; and

FIGS. 11 and 12 are cross-sectional views showing a configuration of a ferroelectric memory according to a third embodiment of the present invention.

### DETAILED DESCRIPTION OF THE INVENTION

### First Embodiment

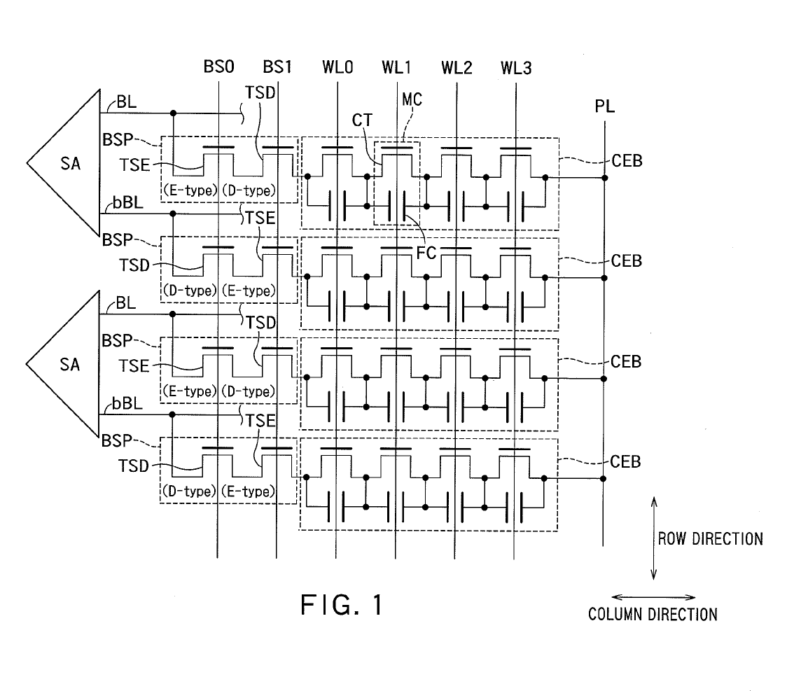

FIG. 1 is a circuit diagram showing a configuration of a ferroelectric memory according a first embodiment of the present invention. The ferroelectric memory of the first embodiment is a “series connected TC unit type ferroelectric RAM”. The series connected TC unit type ferroelectric RAM is a memory which consists of series connected memory cells each having a transistor having a source terminal and a drain terminal and a ferroelectric capacitor inbetween said two terminals.

The ferroelectric memory of the first embodiment comprises a plurality of word lines WLi (i is an integer) extending in a row direction, a plurality of bit lines BL and bBL extending in a column direction perpendicular to the row direction, a plurality of plate lines PL extending in the row direction, and block selection parts BSP.

One memory cell MC stores binary data or multi-bit data in its ferroelectric capacitor. The memory cell MC is provided at the intersection of the word line WLi with the bit line BL, bBL. Each word line WLi is connected to gates of cell transistors CT arranged in the row direction or serves as the gate. Each bit line BL, bBL is connected to sources or drains of cell transistors CT arranged in the column direction.

The ferroelectric memory comprises a plurality of cell blocks CEB each of which is configured by connecting serially a plurality of memory cells MC each of which includes a ferroelectric capacitor FC and a cell transistor CT connected in parallel. An end of the cell block CEB is connected to an end of the block selection part BSP. The other end of the cell block CEB is connected to the plate line PL. The other end of the block selection part BSP is connected to the bit line BL or bBL. That is, the bit lines BL and bBL are connected via the block selection parts BSP to the cell blocks CEB, respectively.

The block selection part BSP includes an enhancement transistor TSE and a depletion transistor TSD. The enhancement transistor TSE and the depletion transistor TSD are controlled by a block selective line BS0 or BS1. The block selection part BSP can connect the bit line BL or bBL selectively to the bit line BL or bBL.

A sense amplifier SA is connected to the bit line pair BL, bBL. The sense amplifier SA detects data from memory cells transmitted in the bit line pair BL, bBL during data read. The sense amplifier SA can apply to voltage to the bit line pair BL, bBL to write data in the memory cells MC during data write. The first embodiment can operate in a 1T1C mode or a 2T2C mode.

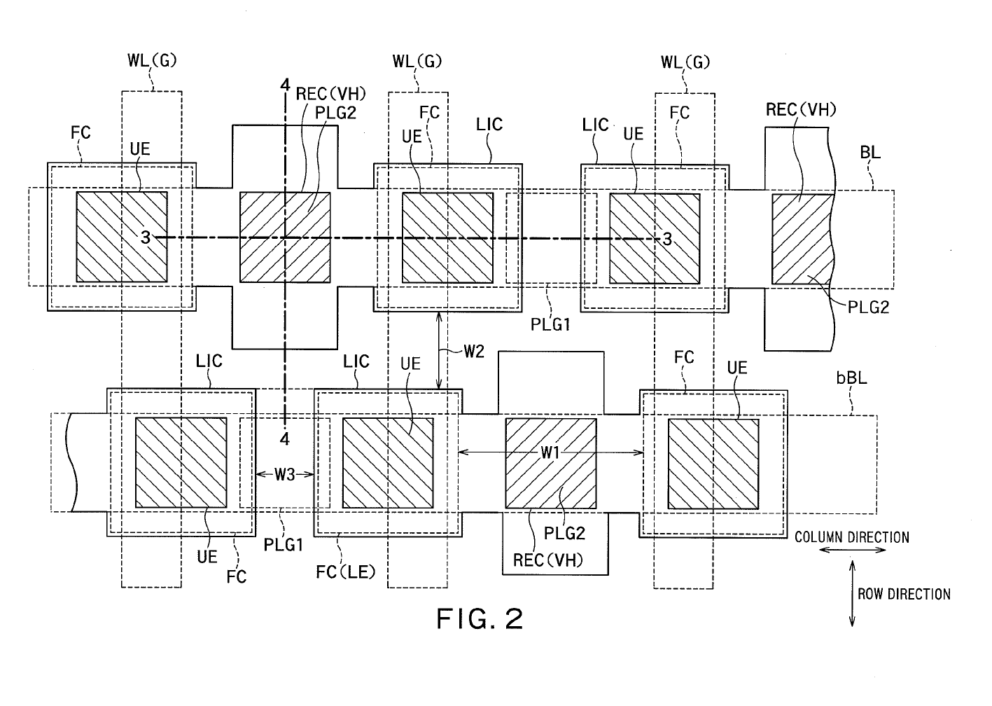

FIG. 2 is a layout diagram showing a planar configuration of part of the ferroelectric memory. A plurality of the ferroelectric capacitors FC are arranged in a direction the bit lines BL, bBL extend (column direction) to configure the cell block. Every two upper electrodes UE of the ferroelectric capacitors FC included in the cell block are connected to each other by a local interconnection LIC. The local interconnection LIC is further connected to an electrode plug PLG2 within a via hole VH.

The word line WL also serves as a gate electrode G for the cell transistor CT and extends in the row direction. The word line WL is formed below the ferroelectric capacitor FC to be isolated from the ferroelectric capacitor FC.

A first electrode plug PLG1 is formed below a lower electrode LE between two local interconnections LIC adjacent to each other in the column direction. The first electrode plug PLG1 connects the lower electrode LE to the source or the drain of the cell transistor CT.

Because a side surface of the ferroelectric capacitor FC is formed in a forward tapered shape, a plane size of the upper electrode UE is smaller than that of the lower electrode LE shown by broken lines in FIG. 2.

Two cell blocks adjacent to each other in the row direction are arranged in order to be shifted from each other in the column direction by a half pitch of the local interconnection LIC.

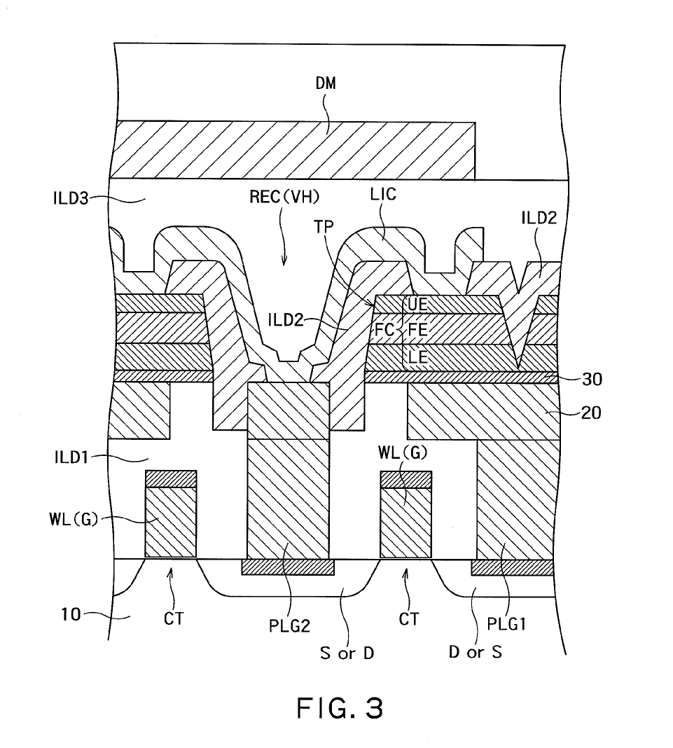

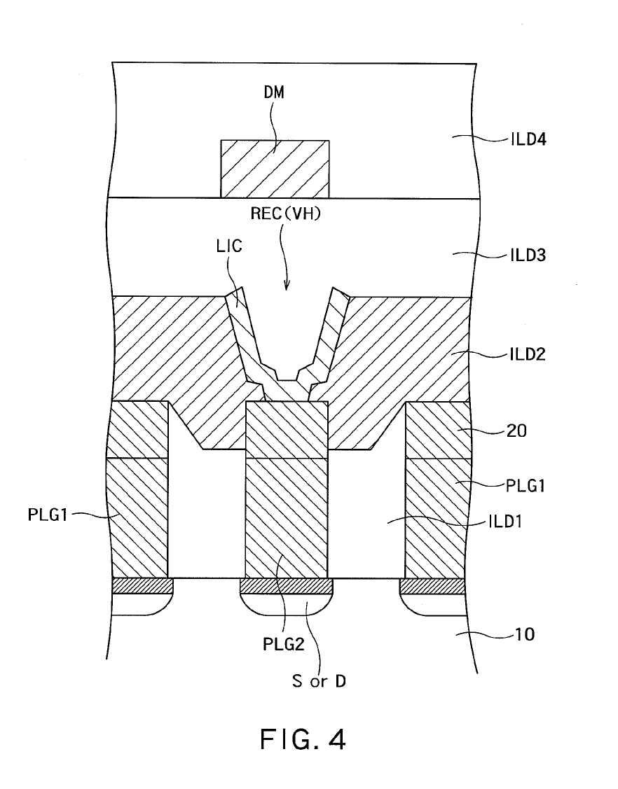

FIG. 3 is a cross-sectional view along a line 3-3 shown in FIG. 2 (column direction). FIG. 4 is a cross-sectional view along a line 4-4 shown in FIG. 2 (row direction). A plurality of the cell transistors CT are formed on a semiconductor substrate 10. A first interlayer dielectric film ILD1 is provided on the source S or the drain D of the cell transistor CT and a side and top surfaces of the gate electrode G.

The first and second electrode plugs PLG1 and PLG2 pass through the first interlayer dielectric film ILD1 to be connected to either the source S or the drain D of the cell transistor CT.

A metallic plug 20 is formed on the first electrode plug PLG1. A conductive barrier film 30 is provided on the metallic plug 20.

The lower electrode LE is provided on the barrier film 30. The lower electrode LE is electrically connected via the barrier film 30 and the metallic plug 20 to the first electrode plug PLG1. A ferroelectric film FE is provided on the lower electrode LE. The upper electrode UE is provided on the ferroelectric film FE. The upper electrode UE, the ferroelectric film FE, and the lower electrode LE constitute the ferroelectric capacitor FC.

A part of top surface and a side surface of the ferroelectric capacitor FC are covered by a second interlayer dielectric film ILD2. Other part of top surface of the ferroelectric capacitor FC is not covered by the second interlayer dielectric film ILD2 and is connected to the local interconnection LIC. The second interlayer dielectric film ILD2 can be a laminated film comprising a hydrogen barrier film covering the side surface of the ferroelectric capacitor FC and an insulation film on the side surface of the ferroelectric capacitor with the hydrogen barrier film interposed therebetween.

A bottom surface of the ferroelectric capacitor FC is covered by the barrier film 30. A part of top surface and the entire side surface of the ferroelectric capacitor FC are covered by the second interlayer dielectric film ILD2. Thus, hydrogen entering the ferroelectric capacitor FC after its manufacturing can be suppressed to some extent.

The local interconnection LIC connects upper electrodes UE of two ferroelectric capacitors FC adjacent to each other in the column direction on sides of the second electrode plug PLG2. The local interconnection LIC is further connected to the second electrode plug PLG2. The upper electrodes UE of the two ferroelectric capacitors FC are connected via the second electrode plug PLG2 between the UEs to the source S or the drain D of the cell transistor CT.

The local interconnection LIC is electrically isolated from the ferroelectric film FE and the lower electrode LE by the second interlayer dielectric film ILD2 on the side surface of the ferroelectric capacitor FC. The second interlayer dielectric film ILD2 is formed along the side surface of the ferroelectric capacitor FC formed in a forward tapered shape.

Meanwhile, lower electrodes LE of two ferroelectric capacitors FC adjacent to each other in the column direction on the first electrode plug PLG1 are connected to the first electrode plug PLG1 and via the first electrode plug PLG1 to the drain D or the source S of the cell transistor CT.

Thus, the ferroelectric capacitor FC and the cell transistor CT are connected to each other in parallel to constitute the memory cell MC. The memory cells MC arranged in the column direction are serially connected by the first electrode plug PLG1, the second electrode plug PLG2, and the local interconnection LIC to constitute the cell block CEB.

A third interlayer dielectric film ILD3 is deposited on the local interconnection LIC. A dummy metal layer DM is further provided on the third interlayer dielectric film ILD3. A fourth interlayer dielectric film ILD4 is provided on the dummy metal layer DM.

The dummy metal layer DM is for preventing the fourth interlayer dielectric film ILD4 in a memory region from dished when interconnections required for a peripheral logic circuit in the memory region are formed. Thus, it suffices that the dummy metal layer DM is in a floated state or grounded.

A first via hole VH is formed in the second interlayer dielectric film ILD2 on the second electrode plug PLG2. The local interconnection LIC is formed along an inner wall of the via hole VH.

Conventionally, the local interconnection LIC has been connected to the second electrode plug PLG2 by a tungsten plug (not shown) formed on the second electrode plug PLG2. MO-CVD is required for forming the tungsten plug.

However, according to the first embodiment, the local interconnection LIC is formed by sputtering metallic materials on the inner wall of the via hole VH without using the tungsten plug. Accordingly, MO-CVD does not need to be used after the ferroelectric memory FC is produced. Thus, generation of hydrogen can be suppressed after the ferroelectric memory FC is produced.

According to the first embodiment, when the second interlayer dielectric film ILD2 is deposited, a recess REC is formed on the second electrode plug PLG2 in a self-alignment manner. A first gap W1 (see FIG. 2) between two ferroelectric capacitors FC adjacent to each other in the column direction on the sides of the second electrode plug PLG2 must be larger than twice the deposited thickness of the second interlayer dielectric film ILD2.

Preferably, recesses or grooves are not provided between two adjacent cell blocks and between two ferroelectric capacitors FC adjacent to each other on the first electrode plug PLG1. This is because the local interconnection LIC must be patterned accurately. A second gap W2 (see FIG. 2) between two cell blocks adjacent to each other in the row direction is preferably smaller than twice the deposited thickness of the second interlayer dielectric film ILD2. A third gap W3 (see FIG. 2) between two ferroelectric capacitors FC adjacent to each other in the column direction on the first electrode plug PLG1 is also preferably smaller than twice the deposited thickness of the second interlayer dielectric film ILD2.

Further, if positions of the local interconnections LIC for the respective cell blocks coincide with each other in the row direction, the recesses REC adjacent to each other in the row direction may become connected, resulting in a groove extending in the row direction. If such a groove is formed, the local interconnection LIC in the groove cannot be removed by lithography and etching. Thus, the local interconnection LIC remains in the groove, causing a plurality of the local interconnections LIC adjacent to each other in the row direction to be shortened electrically.

According to the first embodiment, two adjacent cell blocks are arranged to be shifted from each other by a half pitch of the local interconnection LIC in the column direction. A column direction width (length) of the local interconnection LIC is 1 pitch. In other words, the first electrode plug PLG1 is adjacent to the second electrode plug PLG2 in the row direction. Thus, the recesses REC are not arranged successively in the row direction but arranged in a checker flag shape. As a result, the recesses REC do not become connected in the cell blocks adjacent to each other in the row direction and the local interconnections LIC adjacent to each other in the row direction can be disconnected reliably from each other.

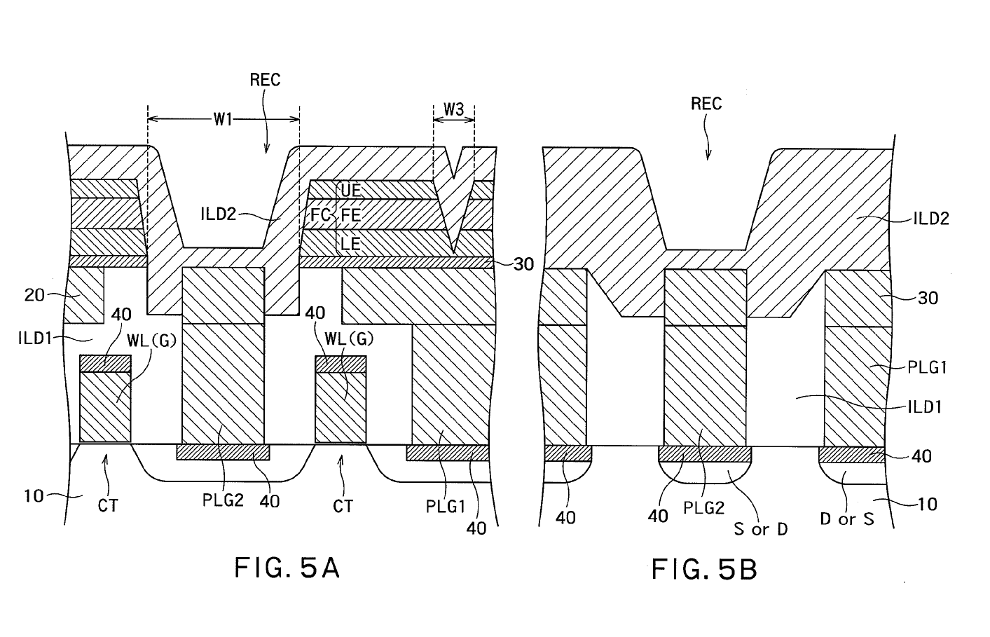

FIGS. 5A, 5B, 6A, 6B, 7A, 7B, 8A, and 8B show a manufacturing method of the ferroelectric memory according to the first embodiment. FIGS. 5A, 6A, 7A, and 8A correspond to FIG. 3. FIGS. 5B, 6B, 7B, and 8B correspond to FIG. 4. As shown in FIGS. 5A and 5B, the cell transistor CT is formed on a surface of the semiconductor substrate 10. To reduce an interconnection resistance, a silicide layer 40 can be formed on the gate electrode G, the source S, and the drain D. The semiconductor substrate 10 is a silicon substrate, for example.

The first interlayer dielectric film ILD1 is then deposited on the gate electrode G, the source S, and the drain D by LP-CVD (Low Pressure-CVD) or plasma CVD. The first interlayer dielectric film ILD1 is, for example, a BPSG film or TEOS film, or a laminated film thereof. The first interlayer dielectric film ILD1 is then flattened by CMP (Chemical Mechanical Polishing). A contact hole reaching the source S or the drain D is formed between gate electrodes G adjacent to each other in the column direction by lithography and RIE (Reactive Ion Etching).

A laminated metallic film of Ti (titanium) or TiN and W (tungsten) is deposited in the contact hole by MO-CVD or ALD (Atomic Layer Deposition). The laminated metallic film is then flattened by CMP, so that the first electrode plug PLG1 and the second electrode plug PLG2 are formed. Burying metallic plugs in contact holes as described above is called a damascene method. Because the ferroelectric capacitor FC is not formed yet, MO-CVD can be used.

The metallic plug 20 is formed on the first and second metallic plugs PLG1 and PLG2 by the damascene method. The barrier film 30 is formed on the second metallic plug PLG2.

The ferroelectric capacitor FC is then formed on the barrier film 30. More specifically, a material for the lower electrode such as iridium is deposited on the barrier film 30 by sputtering. A ferroelectric film such as a PZT film or an SBT film is deposited on the material for the lower electrode by sputtering, MO-CVD, or sol-gel method. A material for the upper electrode such as an IrO₂ film is deposited on the ferroelectric film by sputtering. A mask material such as a TEOS film is deposited on the material for the upper electrode by plasma CVD.

The mask material is processed in a pattern of the ferroelectric capacitor FC by lithography and RIE. The material for the upper electrode, the ferroelectric film, and the material for the lower electrode are etched successively by using the mask material as a mask with RIE. At this time, the side surface of the ferroelectric capacitor FC is formed in a forward tapered shape. The forward tapered shape means an inclined side of a trapezoid whose lower side is longer than an upper side in a cross-section. Because the side surface of the ferroelectric capacitor FC is formed in a forward tapered shape as described above, the second interlayer dielectric film ILD2 can cover the ferroelectric capacitor FC excellently. An edge of the ferroelectric capacitor FC can be prevented from exposed when the via hole VH is formed.

After the ferroelectric capacitor FC is formed, a hydrogen barrier film such as Al₂O₃ is deposited by sputtering or ALD. Further, an insulation film is deposited on the hydrogen barrier film by plasma CVD. The hydrogen barrier film and the insulation film constitute the second interlayer dielectric film ILD2. The recess REC is formed only on the second plug PLG2 in a self-alignment manner. This is because twice the thickness of the second interlayer dielectric film ILD2 is smaller than the first gap W1 but larger than the second gap W2 and the third gap W3.

To form the via hole easily, the flat part of the second interlayer dielectric film ILD2 is made thin by etching back. The second interlayer dielectric film ILD2 covering the top end of the ferroelectric capacitor FC is preferably rounded to some extent. Thus, a configuration shown in FIGS. 5A and 5B is obtained.

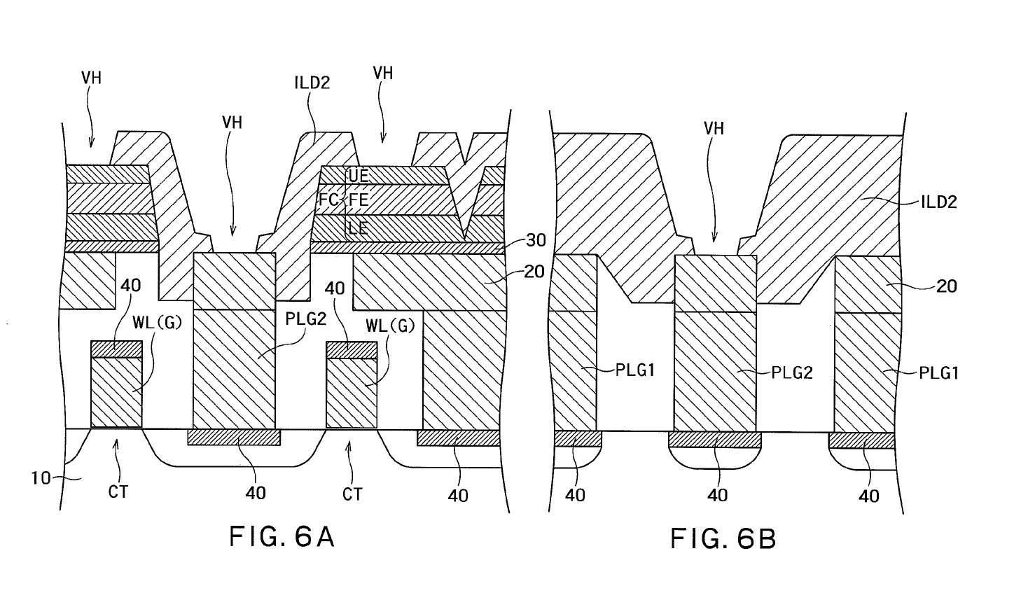

As shown in FIGS. 6A and 6B, the via hole VH is formed on the ferroelectric capacitor FC and the second electrode plug PLG2. At this time, the second interlayer dielectric film ILD2 is patterned using a multilayer resist process, in such a manner that parts of surfaces of the upper electrode UE and the second electrode plug PLG2 are exposed.

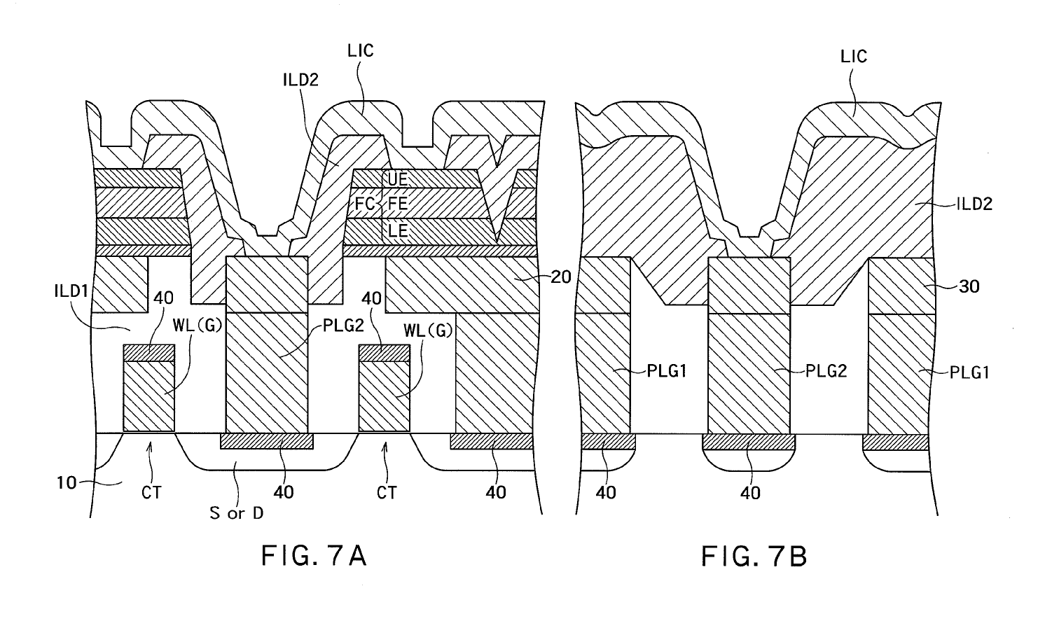

As shown in FIGS. 7A and 7B, a single layer film such as Ir, TiN, TiAlN, IrO₂, Ru, or SrRuO₂ or a laminated film of two or more layers of such materials is deposited on the second interlayer dielectric film ILD2, the upper electrode UE, and the second electrode plug PLG2 by sputtering. The metallic film is processed into the local interconnection LIC.

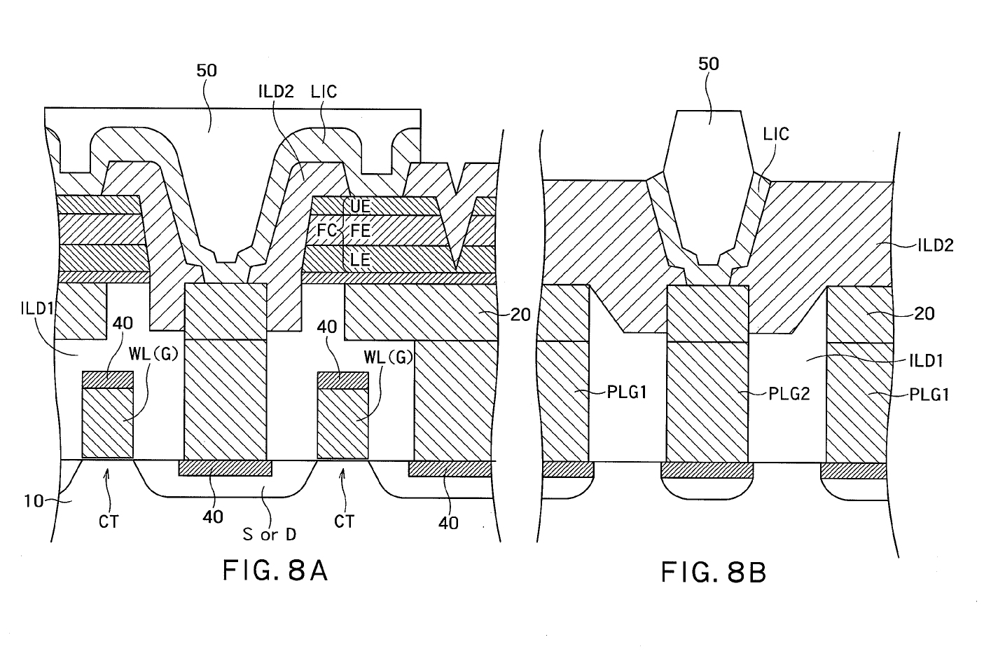

As shown in FIGS. 8A and 8B, an insulation film 50 such as TEOS is deposited on the metallic film. The insulation film 50 is a laminated film of a hydrogen barrier film and TEOS, for example. The insulation film 50 is then flattened by CMP. Further, the insulation film 50 is patterned into a pattern of the local interconnection LIC by lithography and RIE. The metallic film is etched by using the insulation film 50 as a mask. Thus, the local interconnection LIC is formed as shown in FIGS. 8A and 8B. Because the cell block is shifted by a half pitch in the column direction as shown in FIG. 2, the recesses REC (via holes VH) do not continue in the row direction but are separated from each other discontinuously.

The third interlayer dielectric film ILD3 is then deposited by CVD and flattened by CMP. The dummy metal layer DM is then formed on the third interlayer dielectric film ILD3. The fourth interlayer dielectric film ILD4 is deposited on the dummy cell layer DM and flattened by CMP. Other interconnections (not shown) are formed thereafter, so that the ferroelectric memory of the first embodiment is completed. The local interconnection LIC at an end of each cell block is connected via the block selection part to the bit line BL.

Because the cell block is shifted by the half pitch of the local interconnection LIC in the column direction in the first embodiment, the recesses REC are separated from each other. The recess REC between ferroelectric capacitors FC adjacent to each other in the column direction on the second electrode plug PLG2 can thus be used for the via hole VH. Accordingly, the first embodiment enables the local interconnection LIC to be formed in the via hole VH without using MO-CVD after the ferroelectric capacitor FC is formed. According to the first embodiment, degradations of characteristics of the ferroelectric capacitor FC caused by hydrogen can be avoided.

### Second Embodiment

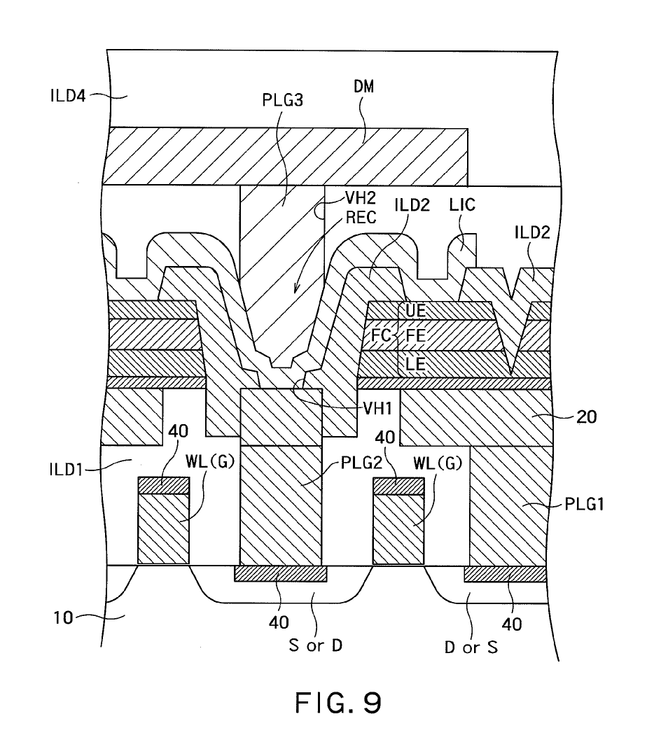

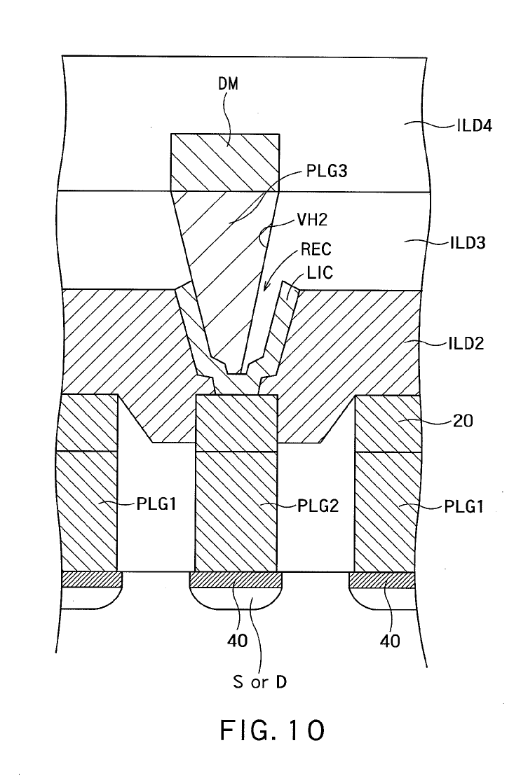

FIGS. 9 and 10 are cross-sectional views showing a configuration of a ferroelectric memory according to a second embodiment of the present invention. FIG. 9 is the cross-sectional view in the column direction. FIG. 10 is the cross-sectional view in the row direction. The second embodiment is different from the first embodiment in that a third electrode plug PGL3 is further provided in the recess REC. Other configurations of the second embodiment can be identical to those of the first embodiment. The via hole VH on the second electrode plug PLG2 according to the first embodiment is called a first via hole VH1 for convenience.

The third electrode plug PLG3 is formed on the first via hole VH1. Thus, the third electrode plug PLG3 contacts the local interconnection LIC at their sides as well as their bottoms. The third electrode plug PLG3 serves to connect the bottom of the local interconnection LIC to the side thereof, resulting in reduced contact resistance of the local interconnection LIC.

The third electrode plug PLG3 connects the local interconnection LIC to the dummy metal layer DM. Thus, the potential of the dummy metal layer DM is stabilized. The third electrode plug PLG3 is an aluminum plug, for example.

The local interconnection LIC is formed by sputtering a metallic film on the inner wall of the recess REC. Thus, the thickness of the local interconnection LIC may be reduced partially when a cell size is downscaled, so that the resistance of the local interconnection LIC may be increased. In the ferroelectric memory, memory cells MC in a cell block are serially connected to each other between the bit line BL and the plate line PL during read or write. If the resistance of the local interconnection LIC is increased, data read and write are difficult to be performed.

The bottom of the local interconnection LIC is electrically connected to the side thereof by the third electrode plug PLG3 in the second embodiment. Thus, the resistance of the local interconnection LIC is reduced. As a result, the data read and write can be performed accurately in the second embodiment.

The plate line PL must be connected to a memory cell MC at an end of the cell block in the ferroelectric memory. To connect the plate line PL to that cell block, the third electrode plug PLG3 can be used. The plate line PL formed of a metallic layer which is the same as the dummy metal layer DM can thus be laid out easily. As described above, the third electrode plug PLG3 can reduce the resistance of the local interconnection LIC and accomplish easy interconnection of the plate line PL.

As shown in FIG. 10, even if the third electrode plug PLG3 (second via hole VH2) is shifted a little in the row direction, the resistance of the local interconnection LIC can be reduced as long as the bottom of the local interconnection LIC is connected to the side thereof in the column direction as shown in FIG. 9. Even if the third electrode plug PLG3 (second via hole VH2) is shifted a little in the column direction, the resistance of the local interconnection LIC can be reduced as long as the bottom of the local interconnection LIC is connected to the side thereof in the row direction. Further, the second embodiment can achieve identical effects as those of the first embodiment.

A manufacturing method of the ferroelectric memory according to the second embodiment is described below. After the steps shown in FIGS. 5A to 8B, the second via hole VH2 is formed in the third interlayer dielectric film ILD3. The second via hole VH2 is formed above the second electrode plug PLG2 in order to reach the local interconnection LIC.

An aluminum plug is loaded in the second via hole VH2 by aluminum reflow. The dummy memory layer DM and the fourth interlayer dielectric film ILD4 are then formed on the third interlayer dielectric film ILD3 and the third electrode plug PLG3 like the first embodiment. Other interconnections (not shown) are formed thereafter, so that the ferroelectric memory of the second embodiment is completed.

### Third Embodiment

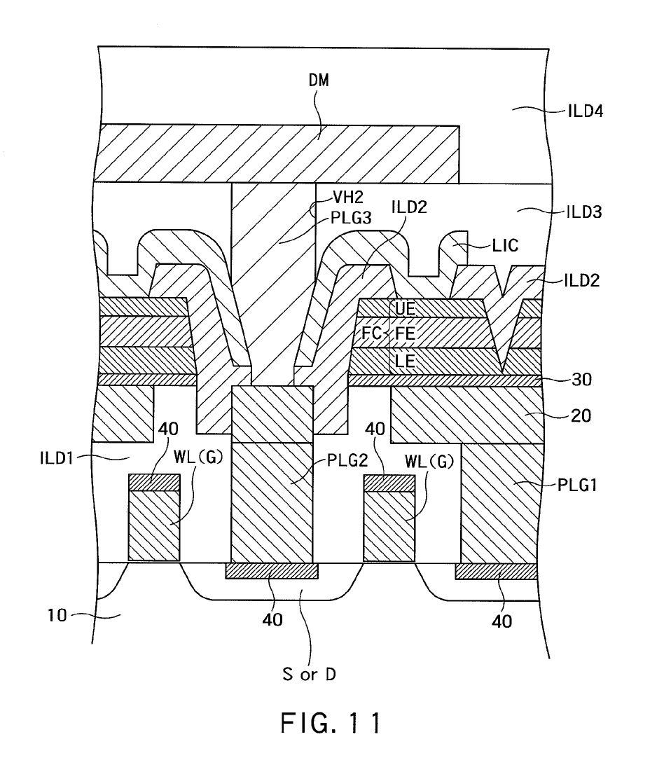

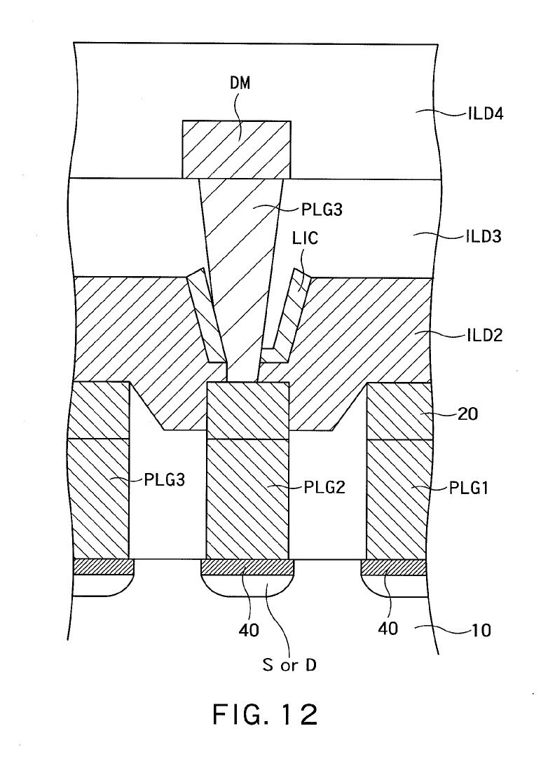

FIGS. 11 and 12 are cross-sectional views showing a configuration of a ferroelectric memory according to a third embodiment of the present invention. FIG. 11 is the cross-sectional view in the column direction, and FIG. 12 is the cross-sectional view in the row direction. According to the third embodiment, the third electrode plug PGL3 passes through the local interconnection LIC and the second interlayer dielectric film ILD2 to be connected to the second electrode plug PLG2. Other configurations of the third embodiment can be identical to those of the second embodiment.

The first via hole VH1 does not need to be provided on the second electrode plug PLG2 when the local interconnection LIC is formed in the third embodiment. This is because the third electrode plug PLG3 can electrically connect the local interconnection LIC to the second electrode plug PLG2 if the second via hole VH2 passes through the local interconnection LIC and the second interlayer dielectric film ILD2. Thus, in the third embodiment, the first via hole VH1 does not need to be formed on the second electrode plug PLG2.

When the memory cell MC is downscaled, the first via hole VH1 is difficult to be formed at the bottom of the recess REC. According to the third embodiment, the second via hole VH2 is formed in order to pass from the flattened surface of the fourth interlayer dielectric film ILD4 without any processes through the third interlayer dielectric film ILD3, the local interconnection LIC, and the second interlayer dielectric film ILD2. Thus, the defectively formed second via hole VH2 can be suppressed. The second via hole VH2 and the third electrode plug PLG3 of the third embodiment can connect the local interconnection LIC to the second electrode plug PLG2 and the bottom of the local interconnection LIC to the side thereof at the same time. Further, the third embodiment can achieve identical effects as those of the second embodiment.

1. A semiconductor memory device comprising:
a semiconductor substrate;
a plurality of transistors on the semiconductor substrate;
a word line connected to a gate of the transistor or serving as the gate;
a first interlayer film on a source and a drain of the transistor;
a first plug passing thorough the first interlayer film to be connected to one of the source or the drain of the transistor;
a second plug passing through the first interlayer film to be connected to the other the source or the drain of the transistor;
a ferroelectric capacitor comprising a lower electrode above the first plug electrically connected to the first plug, a ferroelectric film on the lower electrode, and an upper electrode on the ferroelectric film;
a second interlayer film covering a side surface of the ferroelectric capacitor;
a local interconnection on the second interlayer film connecting the second plug to the upper electrode; and
a bit line connected to the local interconnection, wherein
the upper electrodes of two ferroelectric capacitors adjacent to each other on the second plug in a direction the bit line extends are connected to the second plug by the local interconnection,
the lower electrodes of two ferroelectric capacitors adjacent to each other on the first plug in the direction the bit line extends are connected to the first plug,
a plurality of cell blocks each of which comprises the ferroelectric capacitors connected to each other by the first and the second plugs are arranged,
two cell blocks adjacent to each other in a direction the word line extends are arranged to be shifted from each other by a half pitch of the local interconnection,
a first gap between two ferroelectric capacitors adjacent to each other on sides of the second plug in the direction the bit line extends is larger than twice a deposited thickness of the second interlayer film, and
a second gap between the two cell blocks adjacent to each other in the direction the word line extends is smaller than twice the deposited thickness of the second interlayer film.

2. The device of claim 1, wherein a third gap between two ferroelectric capacitors adjacent to each other on the first plug in the direction the bit line extends is smaller than twice the deposited thickness of the second interlayer film.

3. The device of claim 1, wherein a side surface of the ferroelectric capacitor is constituted in a forward tapered shape.

4. The device of claim 1, wherein the second interlayer film comprises: a hydrogen barrier film covering the side surface of the ferroelectric capacitor; and an insulation film on the side surface of the ferroelectric capacitor with the hydrogen barrier film interposed between the insulation film and the side surface.

5. The device of claim 1, wherein the first plug is adjacent to the second plug in the direction the word line extends.

6. The device of claim 1, wherein the local interconnection is constituted by a single layer film of Ir, IrO₂, TiN, TiAlN, Ru, or SrRuO₂ or by a laminated film of two or more layers of these materials.

7. The device of claim 1, further comprising a third plug which is in a recess constituted in the local interconnection on the second plug, and contacts a bottom and a side of the local interconnection.

8. The device of claim 1, further comprising a third plug passing through the local interconnection above the second plug to be connected to the second plug and contacting the side of the local interconnection.

9. A manufacturing method of a semiconductor memory device comprising:
forming a plurality of transistors on a semiconductor substrate;
forming a first plug connected to one of a source or a drain of the transistor and a second plug connected to the other of the source or the drain of the transistor;
forming a ferroelectric capacitor above the first plug;
forming a second interlayer film on a side surface of the ferroelectric capacitor; and
forming a local interconnection on the second interlayer film, wherein
the local interconnection connects upper electrodes of two ferroelectric capacitors adjacent to each other on the second plug to the second plug,
the first plug is connected to lower electrodes of two ferroelectric capacitors adjacent to each other on the first plug;
a plurality of cell blocks each of which comprises the ferroelectric capacitors connected by the first and the second plugs are arranged,
two adjacent cell blocks are arranged to be shifted by a half pitch of the local interconnection,
a first gap between two ferroelectric capacitors adjacent to each other on sides of the second plug is larger than twice a deposited thickness of the second interlayer film, and
a second gap between adjacent two cell blocks is smaller than twice the deposited thickness of the second interlayer film.

10. The method of claim 9, further comprising forming a third plug in a recess formed in the local interconnection on the second plug in order to contact a bottom and a side of the local interconnection.

11. The method of claim 9, further comprising forming a third plug passing through the local interconnection above the second plug to be connected to the second plug and contacting the side of the local interconnection.
